(19) United States
(12) Patent Application Publication
(10) Pub. No.: US 2014/0284676 A1
(43) Pub. Date: Sep. 25, 2014

(54) SEMICONDUCTOR MEMORY DEVICE AND MANUFACTURING METHOD THEREOF

(71) Applicant: KABUSHIKI KAISHA TOSHIBA, Tokyo (JP)

(72) Inventors: Jungo INABA, Mie (JP); Satoshi NAGASHIMA, Mie (JP); Naoki KAI, Mie (JP); Akiko SEKIHARA, Mie (JP); Karin TAKAYAMA, Mie (JP)

(73) Assignee: KABUSHIKI KAISHA TOSHIBA, Tokyo (JP)

(21) Appl. No.: 14/016,807

(22) Filed: Sep. 3, 2013

(30) Foreign Application Priority Data
Mar. 22, 2013 (JP) 2013-061108

(51) Int. Cl. H01L 27/115; H01L 21/28

(52) U.S. Cl. CPC H01L 27/11517; H01L 21/28008; H01L 27/11563
USPC 257/314; 438/586

(57) ABSTRACT

Plural first charge accumulation layers are arranged on a first gate-insulating film, and divided in the first direction and the second direction. Plural second charge accumulation layers are arranged on a second gate-insulating film and divided in the first direction and the second direction. An intermediate insulating film is arranged on the side surface of the first charge accumulation layers and on the side surface of the second charge accumulation layers. The control electrode includes a side-surface portion, which is arranged on the side surface of the intermediate insulating film, extends in the second direction, and faces via the intermediate insulating film to the side surface of the first charge accumulation layer and the side surface of the second charge accumulation layer, and a pad portion arranged monolithically on the lower portion of the side-surface portion and having a width larger than the film thickness of the side-surface portion.

### CROSS-REFERENCE TO RELATED APPLICATION

This application is based upon and claims the benefit of priority from Japanese Patent Application No. 2013-061108, filed Mar. 22, 2013, the entire contents of which are incorporated herein by reference.

### FIELD

Embodiments described herein relate generally to a semiconductor memory device and a manufacturing method thereof.

### BACKGROUND

To realize an even higher degree of integration for memory devices, a structure having two charge accumulation layers laminated with each other via an insulating film has been suggested. With this structure, on the side surface of the laminate of the charge accumulation layers, a control gate is arranged via an inter-gate-insulating film. For the control gate arranged on the side-wall film of this structure, it is necessary to have a contact connected to it.

### DESCRIPTION OF THE DRAWINGS

FIG. 1 is a schematic perspective view illustrating an example of a memory cell region of a semiconductor memory device according to an embodiment.

FIG. 2 is a schematic plane view illustrating an example of a contact-forming region of the semiconductor memory device according to the embodiment.

FIGS. 3A and 3B show the cross-sectional view taken across B-B′ in FIG. 2.

FIG. 4 is a schematic cross-sectional view illustrating an example of the semiconductor memory device according to the embodiment.

FIG. 5 shows the cross-sectional view taken across A-A′ in FIG. 4.

FIGS. 6A and 6B show the schematic cross-sectional view of an example of the semiconductor memory device according to the embodiment during manufacturing.

FIGS. 7A and 7B show the schematic cross-sectional view of an example of the semiconductor memory device according to the embodiment during manufacturing.

FIG. 8 shows the schematic cross-sectional view of an example of the semiconductor memory device according to the embodiment during manufacturing.

FIG. 9 shows the schematic cross-sectional view of an example of the semiconductor memory device according to the embodiment during manufacturing.

FIG. 10 shows the schematic cross-sectional view of an example of the semiconductor memory device according to the embodiment during manufacturing.

FIG. 11 shows the schematic cross-sectional view of an example of the semiconductor memory device according to the embodiment during manufacturing.

FIG. 12 shows the schematic cross-sectional view of an example of the semiconductor memory device according to the embodiment during manufacturing.

FIG. 13 shows the schematic cross-sectional view of an example of the semiconductor memory device according to the embodiment during manufacturing.

FIG. 14 shows the schematic cross-sectional view of an example of the semiconductor memory device according to the embodiment during manufacturing.

FIG. 15 shows the schematic cross-sectional view of an example of the semiconductor memory device according to the embodiment during manufacturing.

FIG. 16 shows the schematic cross-sectional view of an example of the semiconductor memory device according to the embodiment during manufacturing.

FIG. 17 shows the schematic cross-sectional view of an example of the semiconductor memory device according to the embodiment during manufacturing.

FIGS. 18A and 18B show the schematic cross-sectional view of an example of the semiconductor memory device according to the embodiment during manufacturing.

FIGS. 19A and 19B show the schematic cross-sectional view of an example of the semiconductor memory device according to the embodiment during manufacturing.

FIGS. 20A and 20B show the schematic cross-sectional view of an example of the semiconductor memory device according to the embodiment during manufacturing.

### DETAILED DESCRIPTION

According to an embodiment, there is provided a semiconductor memory device including a contact for a control electrode provided on a side surface of a charge accumulation layer and a manufacturing method thereof.

In general, according to one embodiment, there is provided a semiconductor memory device comprising: a first array of memory cells, each cell in the array positioned between a first semiconductor layer and an intermediate insulator; a second array of memory cells, each cell in the array positioned between the intermediate insulator and a second semiconductor layer; and a control electrode having a first portion having a first width extending across a side surface of a first memory cell in the first array and a second memory cell in the second array and a second portion having a second width located at a position peripheral to the memory cell array.

According to another embodiment, there is provided a semiconductor memory device comprising: a first semiconductor layer that extends in the first direction, a first gate-insulating film arranged on the first semiconductor layer, plural first charge accumulation layers that are arranged on the first gate-insulating film and are separated from each other in the first direction and in the second direction crossing the first direction, an insulating film arranged on the first charge accumulation layers, plural second charge accumulation layers that are arranged on the insulating film and are separated from each other in the first direction and in the second direction, a second gate-insulating film arranged on the second charge accumulation layers, a second semiconductor layer that is arranged on the second gate-insulating film and that extends in the first direction, an intermediate insulating film arranged on the side surface of the first charge accumulation layers and the side surface of the second charge accumulation layers, and a control electrode that is arranged on the side surface of the intermediate insulating film and extends in the second direction and that has a side-surface portion facing the side surface of the first charge accumulation layers and the side surface of the second charge accumulation layers via the intermediate insulating film and a pad portion that is arranged monolithically with the lower portion of the side-surface portion and has a width larger than the film thickness of the side-surface portion.

In the following, embodiments will be explained with reference to the figures. The same keys are used throughout the figures.

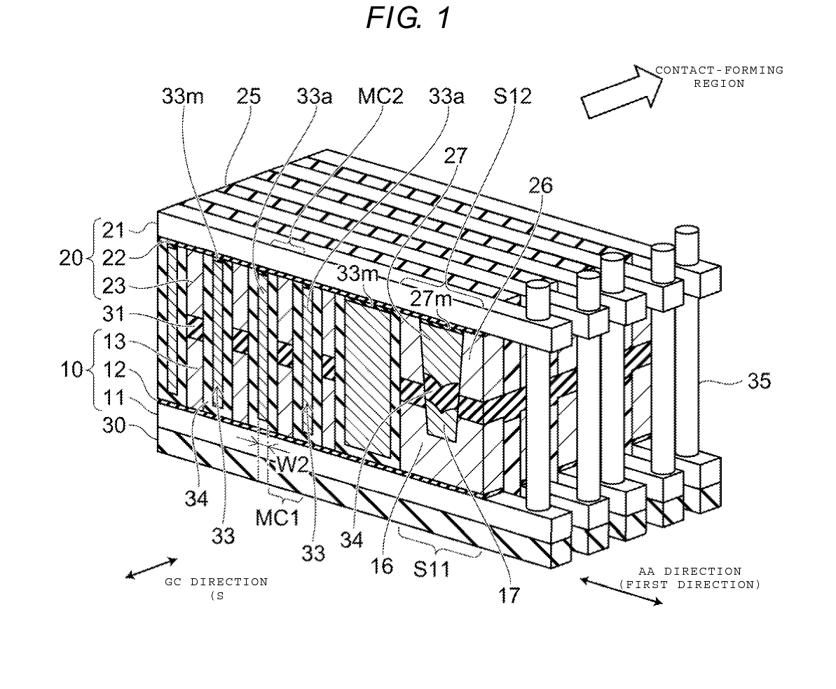

FIG. 1 is a schematic perspective view illustrating an example of the memory cell region of the semiconductor memory device according to an embodiment.

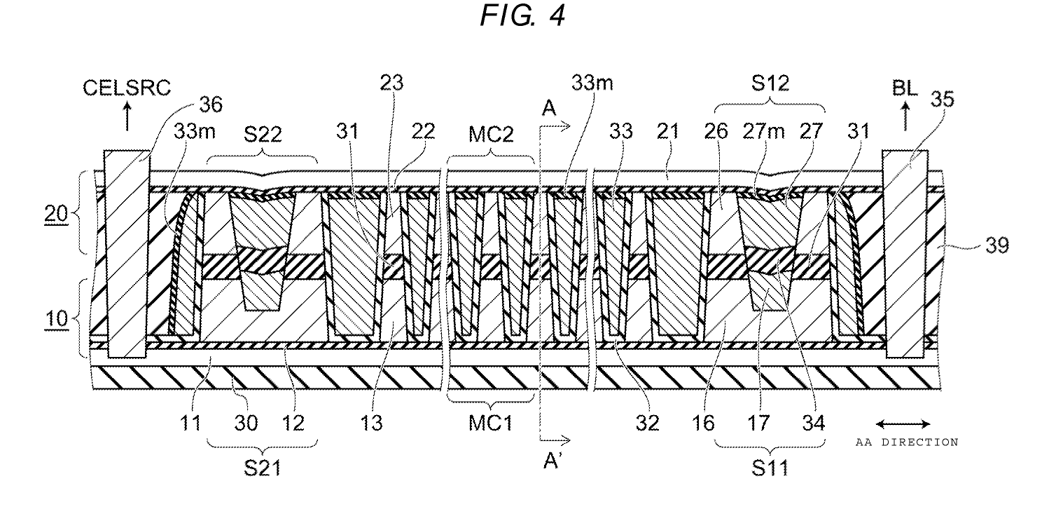

FIG. 4 is a schematic cross-sectional view illustrating an example of the semiconductor memory device according to the embodiment. FIG. 4 corresponds to the cross-sectional view taken across A-A′ (the first direction) in FIG. 1.

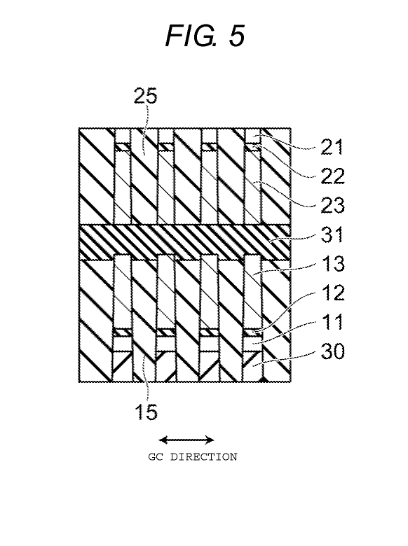

FIG. 5 is a cross-sectional view taken across A-A′ in FIG. 4, and it shows one example. FIG. 5 corresponds to the cross-section taken in the GC direction (the second direction) shown in FIG. 1. The GC direction crosses the AA direction at, e.g., a right angle.

On the base 30 of the insulator layer, a first semiconductor layer 11 is arranged where the channel region or the active region is formed. Here, plural first semiconductor layer portions 11 extending in the first direction AA and are arranged, and spaced, side by side in the second direction GC. A first gate-insulating film (or the first tunnel-insulating film) 12 is formed over selected regions or portions of each of the first semiconductor layer portions 11 and extend thereon in the first direction AA.

On each the first gate-insulating films 12, plurality of first charge accumulation layers 13 are arranged. For example, the first charge accumulation layer 13 is a floating-gate electrode containing polysilicon. Also, the first charge accumulation layer 13 may be a silicon nitride film or another charge-trap film. In addition, the first charge accumulation layer 13 may be a laminated film, including a floating-gate electrode and a charge-trap film. An insulating film 31 is formed on each first charge accumulation layer 13 on the end thereof opposite to the first gate insulating film 12.

On the insulating films 31, a second charge accumulation layer 23 is positioned. For example, the second charge accumulation layer 23 is a floating-gate electrode containing polysilicon. Also, the second charge accumulation layer 23 may be a silicon nitride film or another charge-trap film. In addition, the second charge accumulation layer 23 may be a laminated film, including a floating-gate electrode and a charge-trap film.

A second gate-insulating film (or a second tunnel-insulating film) 22 is arranged on the second charge accumulation layers 23.

A second semiconductor layer 21 that forms the channel region or the active region is arranged on the second gate-insulating films 22. These second semiconductor layer portions 21 extend in the first direction AA and are spaced one from another in the second direction GC.

As best shown in FIG. 5, the base 30, the first semiconductor layer 11, the first gate-insulating film 12 and the first charge accumulation layer 13 are divided into individual portions separated from each other in the GC direction by the interlayer-insulating film 15 extending in the AA direction (the direction going through the paper's surface in FIG. 5. The interlayer insulating film 15 is formed in apertures previously etched through the stack of film layers from which the base 30, the first semiconductor layer 11, the first gate-insulating film 12 and the first charge accumulation layer 13 are formed.

As is also shown in FIG. 5, the second charge accumulation layer 23, the second gate-insulating film 22, and the second semiconductor layer 21 are divided into the individual portions separated from each other in the GC direction by an interlayer-insulating film 25 extending in the AA direction (the direction going through the paper's surface in FIG. 5). As with the insulator insulating film 15, the insulator insulating film 25 is formed into apertures previously etched into the second charge accumulation layer 23, the second gate-insulating film 22, and the second semiconductor layer 21. The base of the interlayer-insulating film 25 is in contact with the insulating film 31 over which the stack of second charge accumulation layer 23, the second gate-insulating film 22, and the second semiconductor layer 21 are formed.

As shown in FIGS. 1 and 4, the charge accumulation layer stack including the first charge accumulation layer 13 and the second charge accumulation layer 23 are also divided into plural portions in the AA direction. That is, plural column-shaped charge accumulation layer stack portions are arranged in a matrix configuration extending in both the AA and GC directions.

On each of the two side surfaces of the charge accumulation layer laminate in the AA direction, a control electrode 33 is arranged within the intermediate insulating film 32. Here, the control electrode 33 extends in the GC direction.

The control electrode 33 is embedded on the inner side of the intermediate insulating film 32 between the charge accumulation layer laminate portions adjacent to each other in the AA direction. The control electrode 33 is arranged to be shared by the first charge accumulation layer 13 and the second charge accumulation layer 23 stacked one over the other via the insulating film 31.

The control electrode 33 is positioned over the intermediate insulating film 32 and is spaced from the a first charge accumulation layer 13 and a second charge accumulation layer 23 on either side thereof by the intermediate insulating film 34, such that the control electrode 33 may be capacitively coupled to the first charge accumulation layer 13 and the second charge accumulation layer 23.

A mask material (insulating film) 33m caps the control electrode and is positioned between the control electrode 33 and the second gate-insulating film 22. The intermediate insulating film 32 spaces and isolates the control electrode 33 from the first gate-insulating film 12.

The semiconductor memory device in the embodiment includes a stacked structure including a first memory cell MC1 and a second memory cell MC2 formed on the first memory cell MC1.

The first memory cell MC1 includes a first semiconductor layer 11, a first gate-insulating film 12, and a first charge accumulation layer 13, and the intermediate insulating film 32 and the control electrode 33 located adjacent to the side of the first charge accumulation layer 13.

The second memory cell MC2 includes a second semiconductor layer 21, a second gate-insulating film 22, and a second charge accumulation layer 23, and the intermediate insulating film 32 and the control electrode 33 located adjacent side of the second charge accumulation layer 23.

The first selecting gate 16 and the second selecting gate 26 for the selecting-gate transistors S11, S12, S21 and S22 are located adjacent to the control electrode 33 on each of the two ends of the row of the plural charge accumulation layer laminate portions in the AA direction.

The second selecting gate 26 is positioned over the first selecting gate 16 with the interlayer-insulating film 31 disposed therebetween. The first selecting gate 16 is disposed over the first semiconductor layer 11 and is spaced and electrically insulated from the first semiconductor layer 11 by the first gate-insulating film 12. The second selecting gate 26 is located adjacent to the second semiconductor layer 21, and is spaced and electrically insulated therefrom by the second gate-insulating film 22.

A first selecting gate line 17 extending in the GC direction (the direction going through the paper's surface in FIG. 4) is embedded in the first selecting gate 16. A second selecting gate line 27 extending in the GC direction is embedded in the second selecting gate 26. Between the second selecting gate line 27 and the second gate-insulating film 22, a mask material (insulating film) 27m is provided.

Between the first selecting gate line 17 and the second selecting gate line 27, an interlayer-insulating film 34 is provided which insulates and separates the first selecting gate line 17 and the second selecting gate line 27 from each other.

The lower-side memory cell unit (having first selecting gate 16) includes the lower-side memory cell MC1 and the selecting-gate transistors S11, S21. The first memory cell array layer 10 includes plural lower-side memory cell units arranged in the GC direction.

The upper-side memory cell unit (having second selecting gate 26) includes the upper-side memory cell MC2 and the selecting gate transistors S12 and S22. The second memory cell array layer 20 includes plural upper-side memory cell units arranged in the GC direction.

Extending between the semiconductor layers 11 and 21 on one end of the memory cell unit is a bit-line contact 35 and the bit-line contact 35 is connected to a bit line (not shown in the figure).

Extending between and connecting the semiconductor layers 11 and 21 on the other end of the memory cell unit is a source-line contact 36, and the source-line contact 36 is connected to a source line not shown in the figure.

Referring still to FIGS. 1 and 4, the upper/lower charge accumulation layers 13 and 23 may be commonly coupled to the control electrode 33 located adjacent thereto, having the intermediate insulating film 32 disposed therebetween.

On the other hand, the lower-side selecting gate 16 and the upper-side selecting gate 26 can be driven independently of the charge accumulation layers and the control electrodes 33. Consequently, via the selecting transistor, it is possible to independently activate the lower-side first semiconductor layer 11 and the upper-side second semiconductor layer 21.

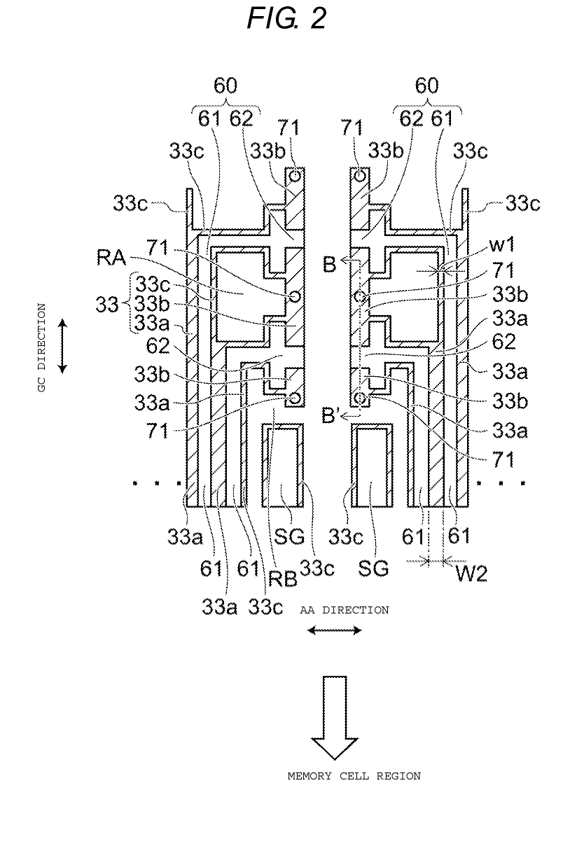

FIG. 2 is a plane view illustrating an example of a contact-forming region where the control electrode 33 extends from the memory cell region and where the contact 71 is positioned.

The contact-forming region is positioned adjacent to the memory cell region in the GC direction. In the contact-forming region, there is the charge accumulation layer stack 60 including a first charge accumulation layer 13 having a second charge accumulation layer 23 formed thereover as shown in FIG. 4. The stack including the first selecting gate 16 and the second selecting gate 26 (FIGS. 1 and 4) are represented as the selecting-gate stack SG.

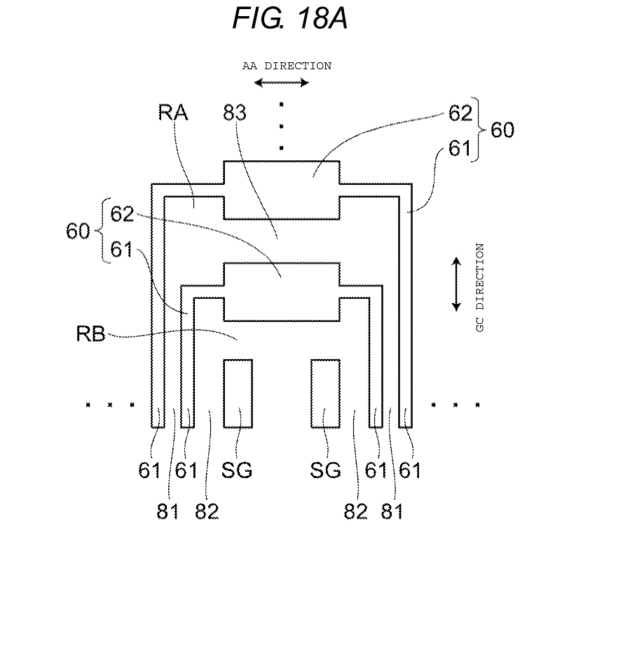

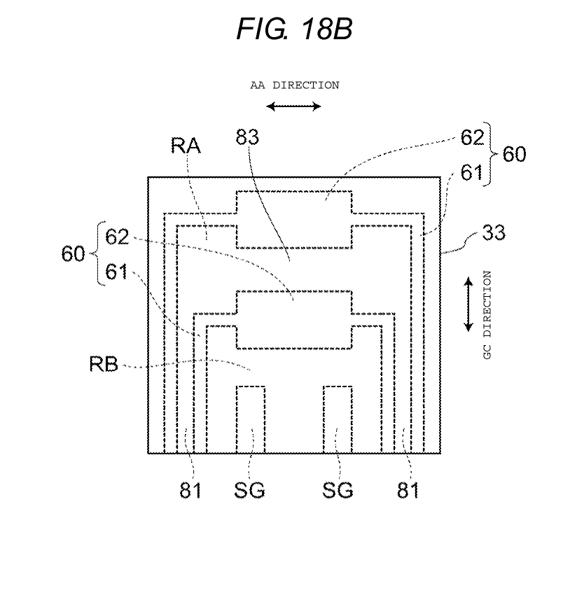

The charge accumulation layer stack 60 has plural line portions 61 extending from the memory cell region in the GC direction. The line portions 61 are separated from each other in the AA direction with a space 81 between the adjacent lines as shown in FIG. 18A. After extending for a prescribed length in the GC direction, the line portions 61 are bent in the AA direction. Here, the charge accumulation layer stack 60 is bent at different positions in the GC direction. As a result, there exists a region RA where the spacing of the adjacent charge accumulation layer stacks 60 is wider than the spacing between the adjacent line portions 61 extending therefrom.

Here, the charge accumulation layer laminate 60 is formed prior to forming the line portions 61 which extend in the AA direction, and it has a wide portion 62 with a width larger than the width thereof in the AA direction. The width of the wide portion 62 in the AA direction and that in the GC direction are larger than the width of the line portions 61 in the AA direction. The plural wide portions 62 are arranged side by side and spaced from one another in the GC direction.

The two selecting-gate portions SG connected to the different cell rows are arranged side by side adjacent to each other in the AA direction. Here, there exists a region RB where the spacing between the line portions 61 is bent in the AA direction and the selecting-gate laminate SG is larger than the spacing between the line portions 61.

Also, a pair of the line portions 61 having a linear symmetric relationship in position with two selecting-gate laminate portions SG sandwiched between them have their end-portions facing each other in the GC direction. In other words, the wide portion 62 has a mirrored structure in the AA direction between the two selecting-gate laminate portions SG.

The control electrode 33 is formed along the side surface of the charge accumulation layer laminate 60. Although not shown in FIG. 2, the control electrode 33 is arranged on the side surface of the charge accumulation layer laminate 60 via the interlayer-insulating film.

The control electrode 33 has a side-surface portion 33a arranged on the side surface of the charge-accumulating layer stack 60. The width of the side-surface portion 33a is nearly equal to the width W2 of the control electrode 33 in the AA direction. The side-surface portion 33a branches into two side-surface portions 33c extending along and around, the side surfaces of the charge accumulation layer stack 60 in the region RA. The width w1 of the side-surface portions 33c is larger than half the spacing w2 between the charge accumulation layer stack portions 60. The width w1 of the side-surface portions 33c is smaller than half the distance between the selecting-gate laminate SG and the charge accumulation layer stack 60. In addition, it is preferred that the width w1 of the side-surface portions 33c be smaller than the width w2 of the side-surface portion 33a.

The control electrode 33 also includes a pad portion 33b formed at the ends of the side-surface portions 33c opposite to the side surface portion 33a. A contact 71 is arranged on each pad portion 33b. Here, there may be plural contacts 71 on each pad portion 33b. In addition, here the two branched side-surface portions 33c are connected to each other in the pad portion 33b.

The width w1 of the side-surface portions 33c is smaller than the width of the region RB in the GC direction. As a result, the side-surface portions 33c arranged on the side surfaces of the charge accumulation layer stack 60 are not connected to the side-surface portions 33c arranged on the side surfaces of the selecting-gate SG.

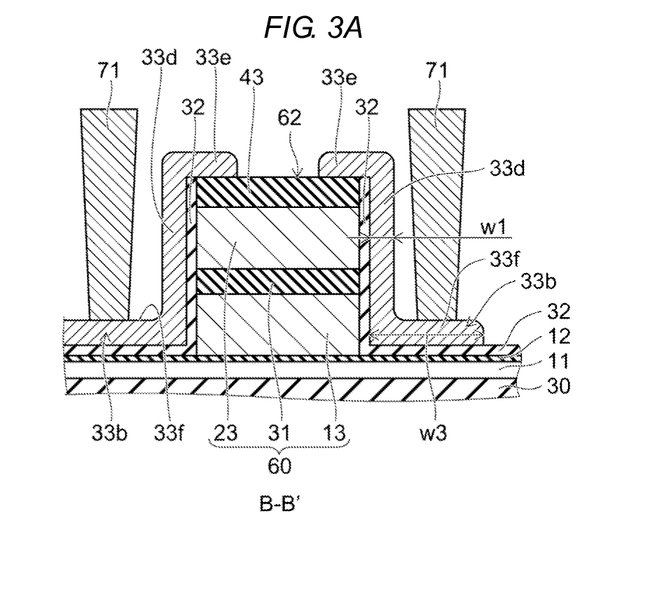

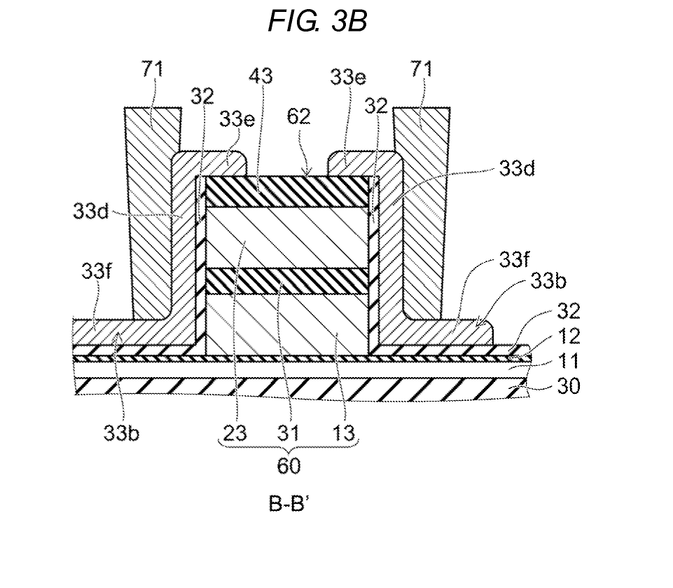

In the following, FIG. 3A is a cross-sectional view taken across B-B′ in FIG. 2, and it shows one example.

The wide portion 62 of the charge accumulation layer stack 60 is positioned, via the first gate-insulating film 12, on the first semiconductor layer 11. On the upper portion of the wide portion 62 of the charge accumulation layer stack 60, the mask material 43 is positioned. The pad portion 33b of the control electrode 33 is extends from the upper surface of the wide portion 62 of the charge accumulation stack 60, along the side surface thereof, and thence over the first gate-insulating film 12. Also, the pad portion 33b is formed on opposed sides of the wide portion 62 in the GC direction, with an open space between the two pad portions 33b at the upper portion of the wide portion 62.

Here, as shown in FIG. 3A, the pad portion 33b includes the portions including a pad upper portion 33e, a pad side-surface portion 33d, and a pad bottom-surface portion 33f. The width of the pad side-surface portion 33d is nearly equal to the width w1 of the side-surface portions 33c. This is because the side-surface portions 33c and the pad side-surface portion 33d are formed continuously on the side surface of the charge accumulation layer laminate 60. In the GC direction, the width w3 of the pad bottom-surface portion 33f of the portion on the first gate-insulating film 12 is larger than the width w1 of the pad side-surface portion 33d. As a result, the contact 71 can be reliably connected to (i.e., landed on) the pad portion 33b.

In addition, as shown in FIG. 3B, one may also adopt a scheme in which the contact 71 is in contact with not only the pad bottom-surface portion 33f, but also the pad side-surface portion 33d. As a result, it is possible to have a lowered contact resistance between the contact 71 and the control electrode 33.

In addition, the pad upper portion 33e and the pad side-surface portion 33d cover the corner portions of the upper surface of the charge accumulation layer laminate 60. As a result, for example, even when offset occurs at a corner portion on the upper surface of the charge accumulation layer stack 60 due to offset of the contact holes during the formation of the contact 71, there is still no cutting of the mask material 43 due to etching, because the pad portion 33b is formed over the corner portion thus protecting the mask material 43. As a result, the lower end of the contact 71 is reliably separated from (not in contact with) the second charge accumulation layer 23 of the wide portion 62, and it is possible to form the contact 71 so that it reaches only the control electrode 33 with a high reliability.

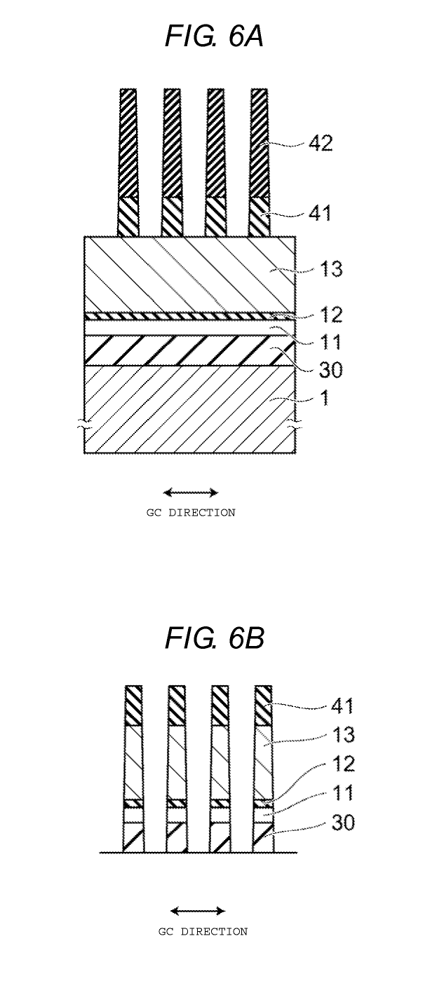

In the following, the method for forming the memory cell array structure of the semiconductor memory device in the embodiment will be explained with reference to FIGS. 6A-17.

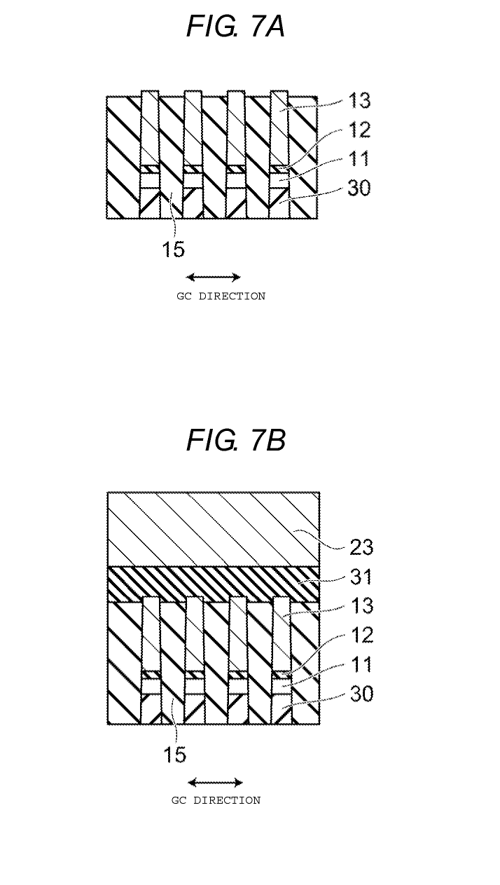

FIGS. 6A to 7B are cross-sectional views taken in the GC direction.

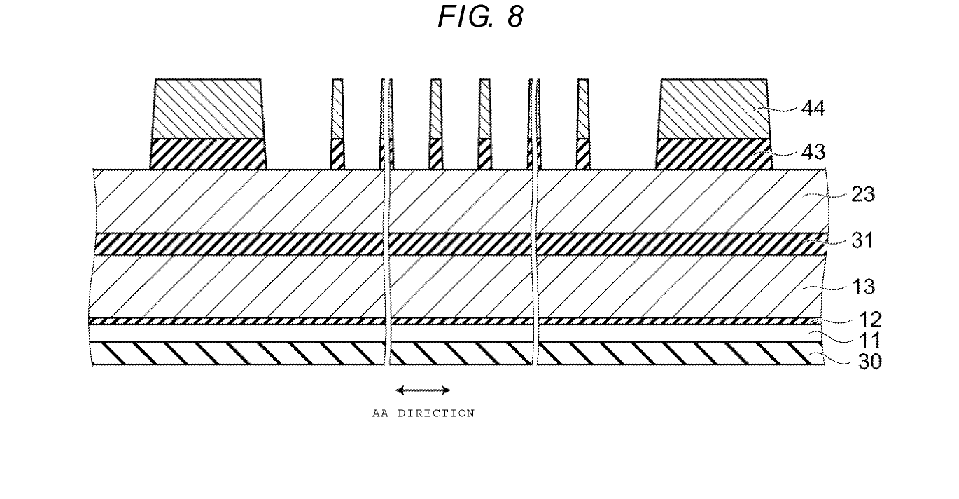

FIGS. 8 to 16 are cross-sectional views taken in the AA direction.

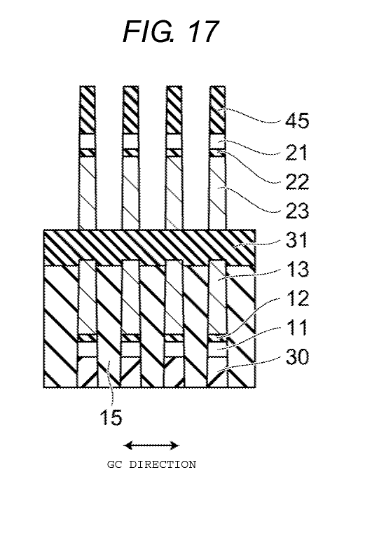

FIG. 17 is a cross-sectional view taken across AA in FIG. 16.

As shown in FIG. 6A, an insulating layer 30 is formed on the substrate 1. Here, the substrate 1 may be a silicon substrate. The substrate 1 will not be shown in the figures of FIG. 6B and thereafter. For example, the insulating layer 30 may be a silicon oxide layer.

On the insulating layer 30, the first semiconductor layer 11, the first gate-insulating film 12 and the first charge accumulation layer 13 are sequentially formed. The first semiconductor layer 11 and the first charge accumulation layer 13 may be polysilicon layers. The first gate-insulating film 12 may be a silicon oxide film.

In the embodiment, the first semiconductor layer 11 is formed as an SOI (silicon-on-insulator) structure. However, the first semiconductor layer 11 may also be formed on the surface of the substrate 1.

Then, on the first charge accumulation layer 13, mask materials 41 and 42 are formed in the AA direction (the direction going through the paper's surface in FIG. 6A). For example, the mask material 41 may be a silicon nitride film, while the mask material 42 may be a silicon oxide film. The mask materials 41, 42 are formed as continuous thin film layers, which are then patterned, such as by photolithographic patterning of layer 42 followed by etching of layer 41 using the pattern of layer 42 as a mask pattern, to transfer the pattern of layer 42 into layer 41.

By, e.g., the RIE (reactive-ion etching) method and using the mask materials 41 and 42, the stack of the first semiconductor layer 11, the first gate-insulating film 12 and the first charge accumulation layer 13 on the substrate 1 is etched in the pattern of the masking layers 41 and 42. As a result, as shown in FIG. 6B, the stack including the insulating layer 30, the first semiconductor layer 11, the first gate-insulating film 12 and the first charge accumulation layer 13 is divided into plural portions in the GC direction. The stack extends in the AA direction (the direction going through the paper's surface in FIG. 6B).

As shown in FIG. 7A, in the trenches between formed by the etching of the stack an interlayer-insulating film (such as a silicon oxide film) 15 is formed such as by chemical vapor deposition. In addition, using the first charge accumulation layer 13 as a polish stop layer, the insulating film 15 is flattened by the CMP (chemical-mechanical polishing) method. In addition, the upper surface of the interlayer-insulating film 15 is recessed below the top of the etched first charge accumulation layer 13 by etching thereof.

Then, as shown in FIG. 7B, an interlayer-insulating film 31 is formed on the interlayer-insulating film 15 and the first charge accumulation layer 13, and on the interlayer-insulating film 31, the second charge accumulation layer 23 is formed. The interlayer-insulating film 31 may be a silicon oxide film, and the second charge accumulation layer 23 may be a polysilicon layer.

Then, as shown in FIG. 8, on the second charge accumulation layer 23, the mask materials 43 and 44 are formed in the GC direction (the direction going through the paper's surface in FIG. 8) and then patterned. For example, the mask material 43 may be a silicon oxide film, while the mask material 44 may be a silicon oxide film.

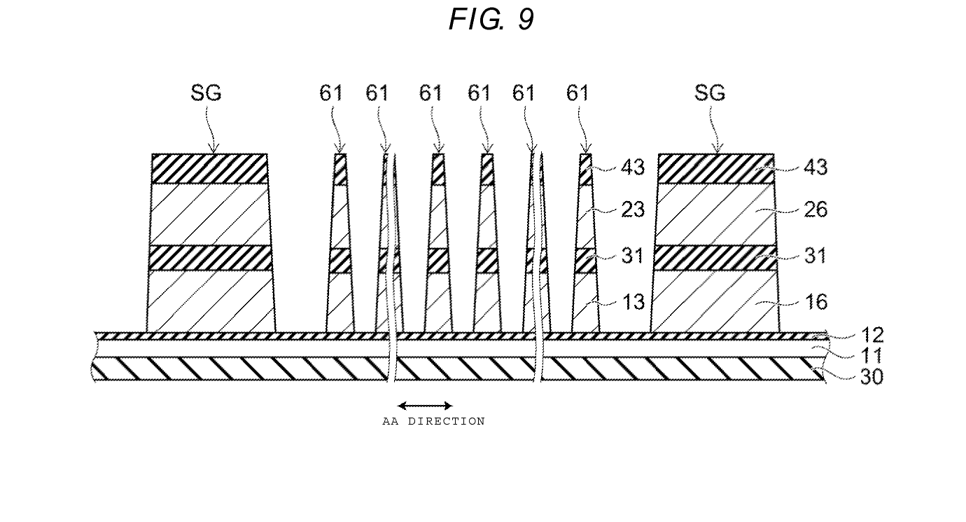

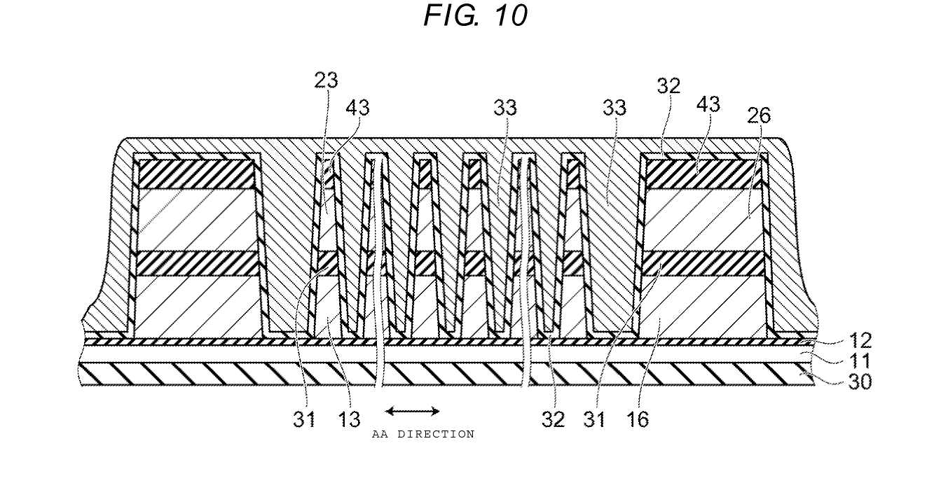

Then, etching using an RIE method and using the mask materials 43 and 44 to transfer a pattern, the stack of the first gate-insulating film 12 is etched to yield the structure as shown in FIG. 9. A portion of the material layer (such as the polysilicon layer) of the first charge accumulation layer 13 becomes the first selecting gate 16 with a width in the AA direction larger than the first charge accumulation layer 13. Also, a portion of the material layer (such as the polysilicon layer) of the second charge accumulation layer 23 becomes the second selecting gate 26 with a width in the AA direction larger than the second charge accumulation layer 23.

By etching as shown in FIG. 6B and etching as shown in FIG. 9, the first charge accumulation layer 13 is processed into column-shaped portions separated from each other in the GC direction and the AA direction. Here, the first selecting gate 16 is also processed into column-shaped portions separated from each other in the GC direction and the AA direction.

In this step of operation, the second charge accumulation layer 23 and the second selecting gate 26 are not separated from each other in the GC direction (the direction going through the paper's surface in FIG. 9) as they extend in the GC direction.

Then, on the first gate-insulating film 12, the intermediate insulating film 32 as shown in FIG. 10 is formed in a conformal way along the side surface and the upper surface of the plural laminate portions separated from each other by the first gate-insulating film 12. The intermediate insulating film 32 may contain oxides of silicon, nitrides of silicon, oxides of hafnium, etc.

The intermediate insulating film 32 is formed on the side surface of the first charge accumulation layer 13 and on the side surface of the second charge accumulation layer 23. The intermediate insulating film 32 is also formed on the side surface of the first selecting gate 16 and the side surface of the second selecting gate 26.

After formation of the intermediate insulating film 32, the control electrode 33 material is embedded between the laminate portions such as by chemical vapor or physical vapor deposition. Here, the control electrode 33 may be a polysilicon film or a tungsten film or other metal film.

The control electrode 33 is embedded between the laminate portions and on the inner side of the intermediate insulating film 32, and it is arranged adjacent to the side surface of the first charge accumulation layer 13 and the side surface of the second charge accumulation layer 23 with the intermediate insulating film 32 therebetween.

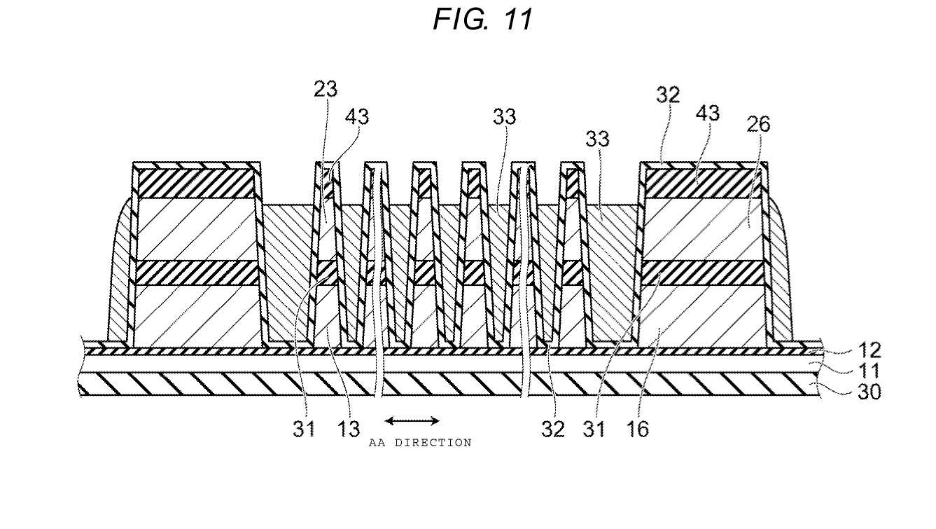

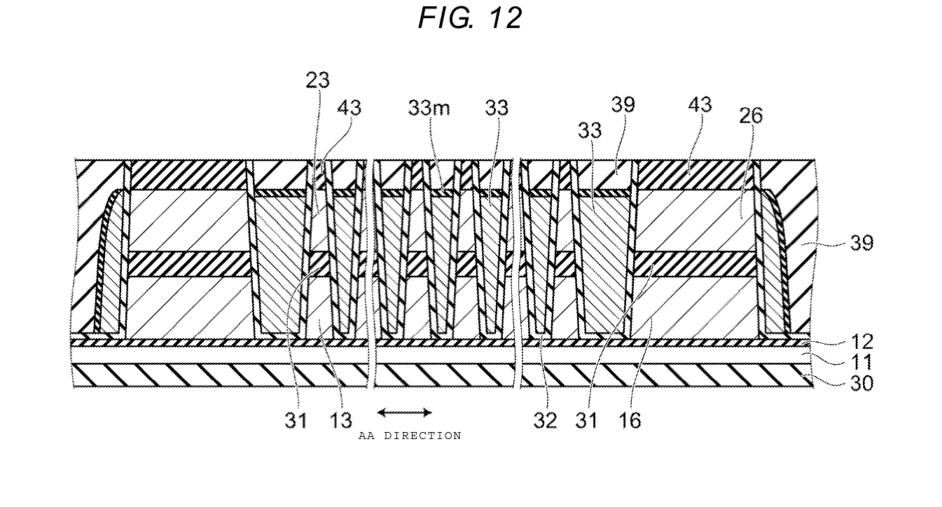

Then, the control electrode 33 is etched back using, e.g., a RIE method, so that the control electrode 33 deposited on the laminate is removed as shown in FIG. 11.

Then, as shown in FIG. 12, on the control electrode 33 in the region between the stack portions, a mask material 33m and an insulating layer 39 are formed. Here, the mask material 33m and the insulating layer 39 may be silicon oxide films.

After deposition of the mask material 33m and the insulating layer 39, a mask material 43, such as a silicon nitride film is used as a polishing stop, and the CMP method is adopted to flatten the upper surface of the entirety of the structure on the substrate.

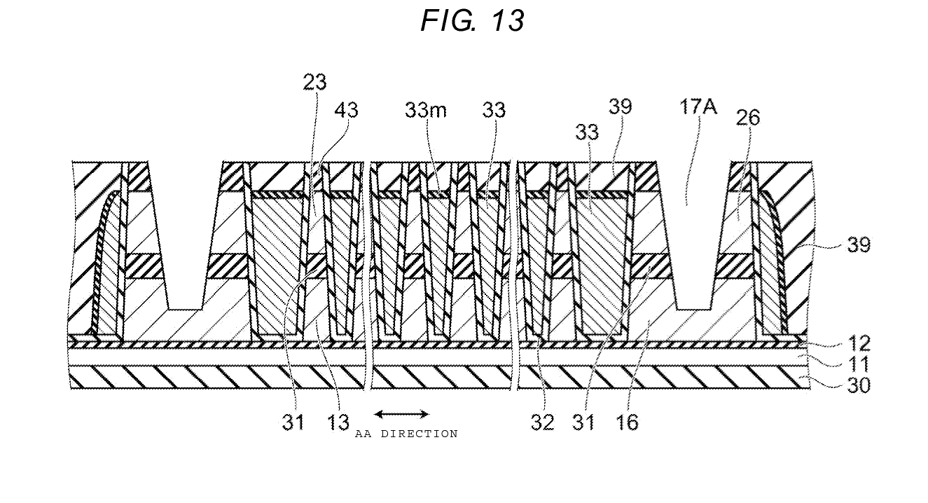

Then, as shown in FIG. 13, for example, the RIE method is used to form the trenches 17A on the stack including the mask material 43, the second selecting gate 26, the interlayer-insulating film 31 and the first selecting gate 16.

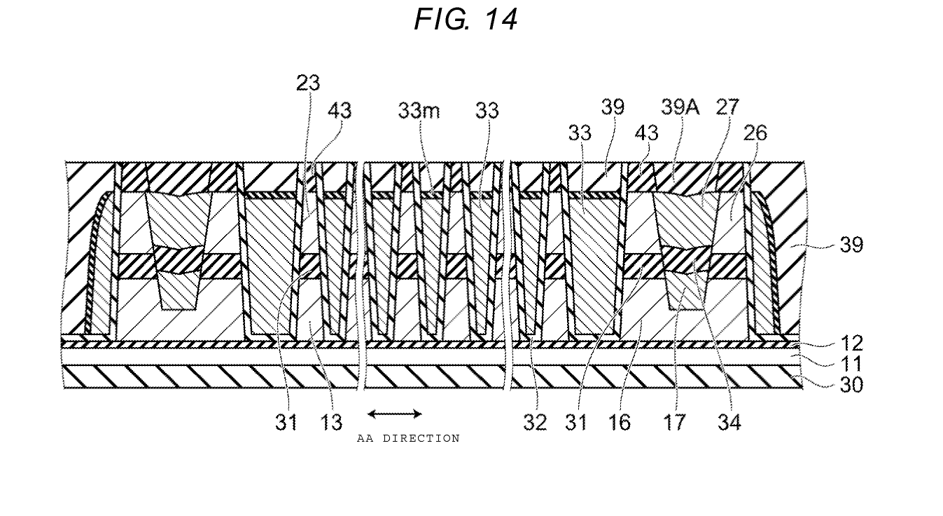

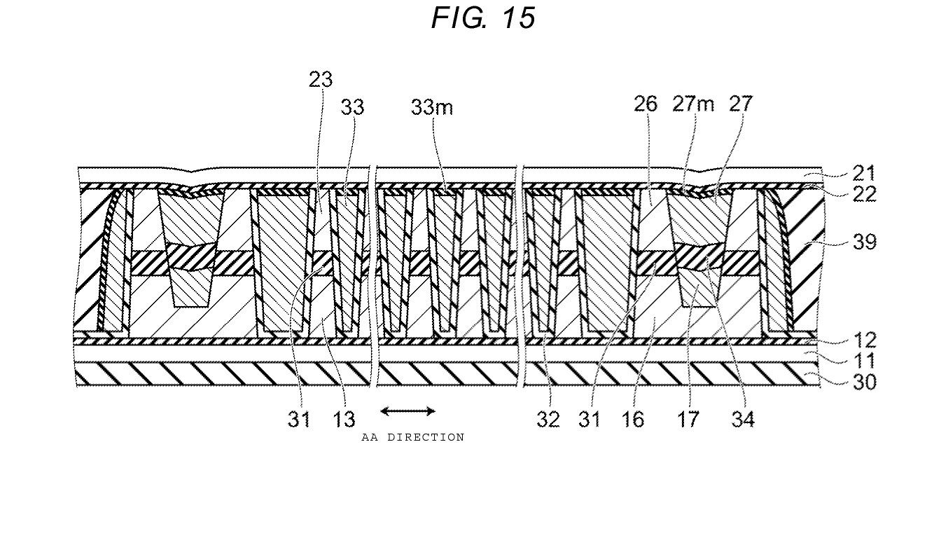

Then, as shown in FIG. 14, in each trench 17A, the first selecting gate line 17, the interlayer-insulating film 34, and the second selecting gate line 27 are sequentially formed.

Just as for the control electrode 33, the selecting gate lines 17 and 27 may be polysilicon films or tungsten films or other metal films.

On the second selecting gate line 27, a cap-insulating film 39A is formed, and its upper surface is flattened by CMP carried out using the mask material 43 as a polishing stop.

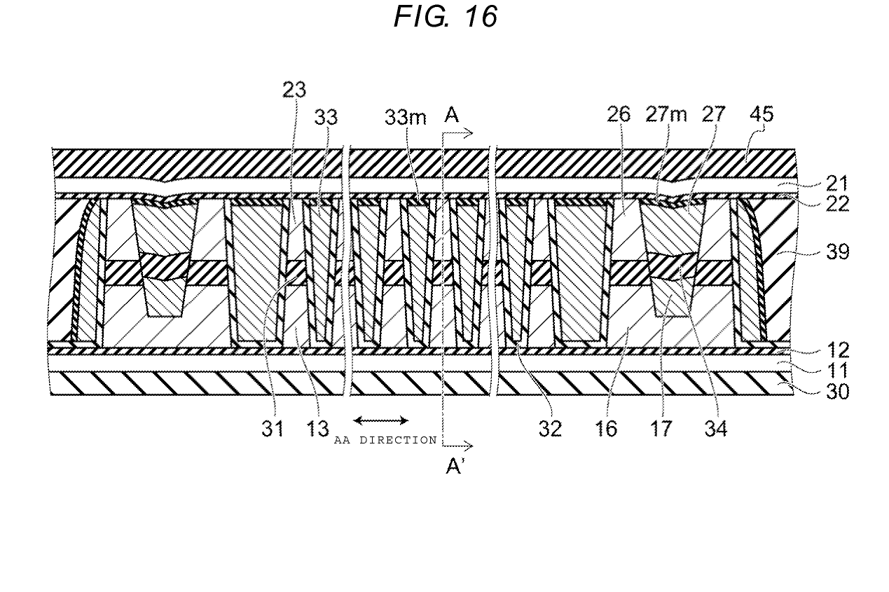

Then, flattening is carried out with the CMP method using the second charge accumulation layer 23 or the control electrode 33 as the polishing stop, and on the flattened surface, as shown in FIG. 15, the second gate-insulating film 22 and the second semiconductor layer 21 are sequentially formed.

The second gate-insulating film 22 may be a silicon oxide film. The second semiconductor layer 21 may be a polysilicon layer.

Then, as shown in FIG. 16 and FIG. 17, a cross-sectional view taken across AA in FIG. 16, on the second semiconductor layer 21, the mask material 45 extending in the AA direction is formed, and then, with, e.g., the RIE method, the second semiconductor layer 21, the second gate-insulating film 22 and the second charge accumulation layer 23 are etched. The mask material 45 may be a silicon nitride film.

The second charge accumulation layer 23 is processed into pole-shaped stacks separated from each other in the AA direction and the GC direction.

Then, as is shown in FIG. 5, in the trenches between the laminate portions separated in the GC direction, an interlayer-insulating film 25 is formed.

In the following, the method for forming the contact structure for connecting the control electrode 33 with the gate wiring (the wiring for providing a potential to the control electrode 33) will be explained with reference to FIGS. 18A-20B and FIG. 2.

FIGS. 18A to 20B and FIG. 2 are schematic plan views illustrating a portion of the contact-forming region of the control electrode 33 in an example.

FIG. 18A corresponds to the schematic plan view of the contact-forming region after the processing shown in FIG. 9. Here, the stack is divided into plural portions on the first gate-insulating film 12 as the backing film.

The charge accumulation layer stack 60 includes a first charge accumulation layer 13 and a second charge accumulation layer 23 formed thereover, with the insulating film 31 formed therebetween. The selecting-gate stack SG includes a first selecting gate 16 and a second selecting gate 26 formed thereover with an insulating layer therebetween.

The charge accumulation layer stack 60 includes plural line portions 61 extending in the GC direction and separated from each other in the AA direction by the inter-line space 81. Here, the inter-line space 81 is nearly equal to the spacing between the line portions 61 shown in FIG. 9. The line portions 61 then bend in the AA direction after extending in the GC direction.

Two selecting-gate portions SG connected to the different cell rows are arranged side by side and adjacent to each other in the AA direction.

In addition, the charge accumulation layer stack 60 has a wide portion 62 that connects a pair of line portions 61. Here, the wide portion 62 is arranged ahead of the bending of the line portions 61 in the AA direction.

The pair of line portions 61 with a linear symmetric position relationship with each other, with two selecting-gate laminate portions SG sandwiched between them, are connected via the wide portion 62 to form a loop at the end-portion in the GC direction. The same number n (n is 1 or a larger natural number) of the line portions 61 as that counted for the selecting-gate laminate portions SG are connected via the wide portion 62.

The width in the AA direction and the width in the GC direction of the wide portion 62 can be larger than the width of the line portions 61 in the AA direction. The plural wide portion 62 are arranged side by side and separated from each other in the GC direction.

The spacing 82 between the line portions 61 and the selecting-gate portions SG can be wider than the inter-line space 81 of the line portions 61. Also, the spacing 83 between the wide portions 62 is wider than the inter-line space 81. The spacing between the selecting-gate laminate portions SG is wider than the inter-line space 81.

After the formation of the charge accumulation layer stack 60 and the selecting-gate stack SG, as shown in FIG. 10, the intermediate insulating film 32 and the control electrode 33 are formed. In the schematic plane views of FIGS. 18A-20B and FIG. 2, the intermediate insulating film 32 is not shown.

As shown in FIG. 18B, the polysilicon film or the metal film as the material film of the control electrode 33 covers the charge accumulation layer laminate 60 and the selecting-gate laminate SG.

Also, the film thickness of the material film of the control electrode 33 is selected to be half the width of the inter-line space 81 or larger. The film thickness of the material film of the control electrode 33 is set to be smaller than the width of the spacing 82. In addition, to shorten the length of the manufacturing operation, it is preferred that the film thickness of the material film of the control electrode 33 be smaller than the inter-line space 81. Consequently, the inter-line space 81 is embedded by the control electrode 33 formed on the side surfaces of the adjacent line portions 61, respectively.

For the regions RA, RB, etc., of the space wider than the inter-line space 81, while the control electrode 33 is formed on the bottom surface as the backing film, the control electrode 33 is formed in a conformal way on the upper surface of the backing film and on the side surface and upper surface of the laminate.

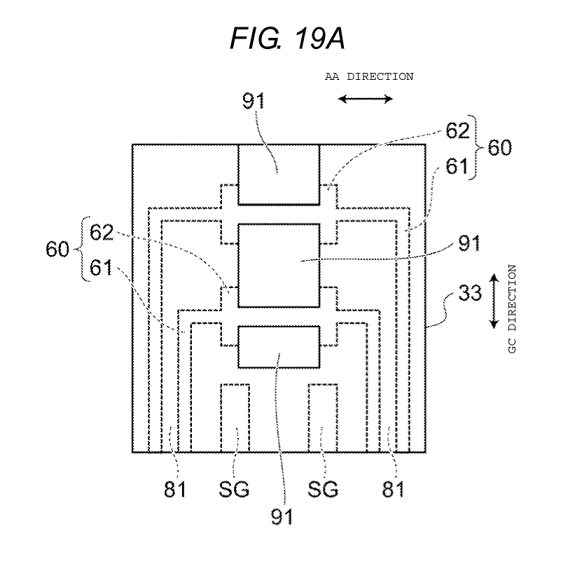

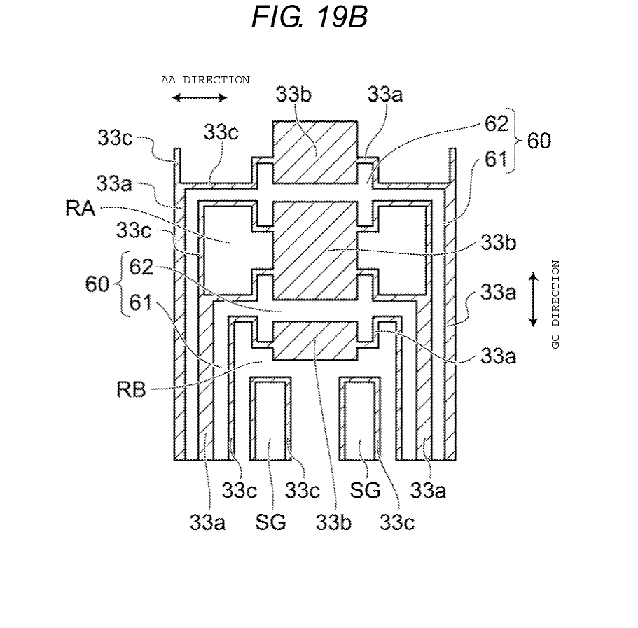

Then, after an etch resistant film is formed on the control electrode 33, patterning is carried out so that, as shown in FIG. 19A, the etch resistant film 91 is selectively left, and hence it extends in the GC direction and is divided in the GC direction by the wide portion 62. Also, the resistant film 91 is formed so that the end-portions of the wide portion 62 in the AA direction are exposed.

As a result, the resistant film 91 covers the region near the end-portion in the GC direction of the wide portion 62 and the region between the wide portions 62 adjacent to each other in the GC direction. In this state, the control electrode 33 is etched back. This etch-back operation for the control electrode 33 corresponds to the operation shown in FIG. 11.

FIG. 19B is a schematic plane view illustrating the state after the removal of the etch resistant film 91 after the etch-back of the control electrode 33. The remaining control electrodes 33 are schematically illustrated by the cross-hatched portions.

The portions except the control electrode 33 formed on the side surface of the selecting-gate laminate SG and the charge accumulation layer laminate 60 and the control electrode 33 covered by the resistant film 91 are removed. That is, the material film of the control electrode 33 on the backing film in the space wider than the inter-line space 81 is removed.

As a result, the material film of the control electrode 33 is left as the side-surface portion 33a of the control electrode 33 on the side surface of the line portions 61 of the charge accumulation layer laminate 60, the side surface of the wide portion 62, the side surface of the selecting-gate laminate SG, and the inter-line space 81.

In addition, the material film of the control electrode 33 is left as the pad portion 33b of the control electrode 33 in the portion covered by the etch resistant film 91. That is, the pad portion 33b is formed near the end-portion in the GC direction of each wide portion 62 and in the region between the wide portions 62 adjacent to each other in the GC direction. The pad portion 33b that is continuous between the adjacent wide portions 62 in the GC direction is arranged.

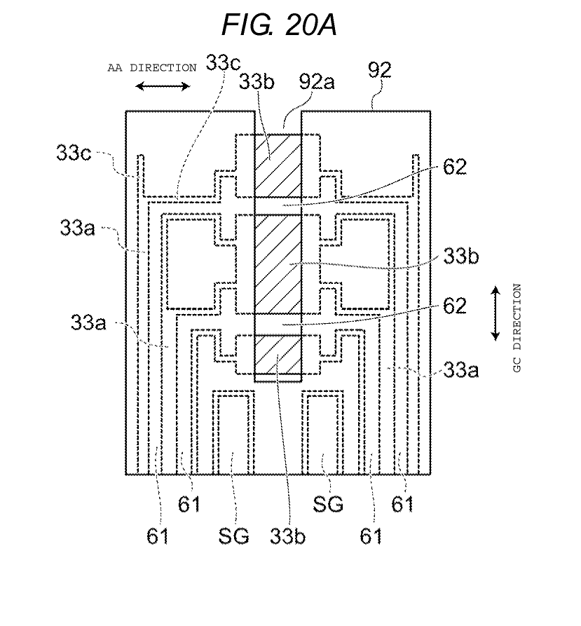

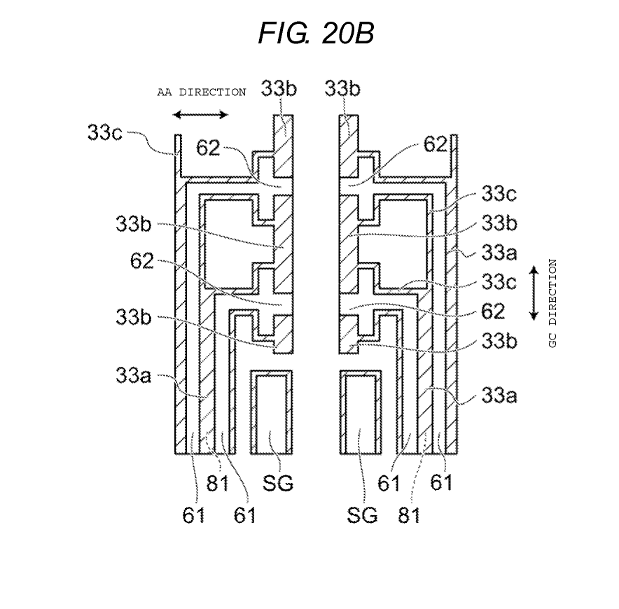

Then, on the entire surface of the structural body shown in FIG. 19B, after the formation of the resistant film 92 shown in FIG. 20A, an opening 92a is formed on a portion of the resistant film 92.

The opening 92a is formed on the wide portion 62 and the pad portion 33b of the control electrode 33 and extending in the GC direction at the position where the wide portion 62 and the pad portion 33b are divided in the AA direction. The two end-portions of the wide portion 62 in the AA direction and the two end-portions of the pad portion 33b in the AA direction are exposed in the opening 92a, while the remaining portions are covered by the resistant film 92.

Then, with, e.g., the RIE method and using the etch resistant film 92, the control electrode 33 and the laminate below the opening 92a are etched.

FIG. 20B is a diagram illustrating the state after the etching and after the removal of the resistant film 92.

The wide portion 62 of the charge accumulation layer laminate 60 is divided in the AA direction. Consequently, the pair of the line portions 61 connected via the wide portion 62 is divided.

Also, the pad portion 33b of the control electrode 33 is also divided in the AA direction. The side-surface portions 33c branched from the side-surface portion 33a are connected with each other, and between the wide portions 62 adjacent to each other in the C-G direction, the pad portion 33b of the control electrode 33 is formed and connected.

The side-surface portion 33a of the control electrode 33 that is embedded in the inter-line space 81 and is shared by the adjacent line portions 61 is branched into two portions at the end-portion in the GC direction. One of the branched side-surface portions 33c goes along the side surface of one of the adjacent line portions 61 and is connected to the pad portion 33b, while the remaining side-surface portion 33c goes along the side surface of the other line portion 61 and is connected to the pad portion 33b. Then, the two branched side-surface portions 33c are merged with each other again at the pad portion 33b.

That is, the side-surface portion 33a of the control electrode 33 that is capacitively coupled via the intermediate insulating film 32 to the first charge accumulation layer 13 and the second charge accumulation layer 23 is connected to the pad portion 33b. The side-surface portion 33a of the control electrode 33 arranged between the adjacent line portions 61 is branched into two portions halfway, and it is then connected to one pad portion 33b.

Then, as shown in FIG. 2 and FIG. 3A or FIG. 3B, a cross-sectional view taken across B-B′ in FIG. 2, the word-line contact 71 is formed on the pad portion 33b of the control electrode 33.

The width of the pad portions 33b in the AA direction and in the GC direction is larger than the width of the side-surface portions 33a (the width in the AA direction). Consequently, the lower end of the contact 71 does not overlie the control electrode 33 and the other elements and reach the other elements, so it is possible to form the contact 71 so that it reaches only the control electrode 33 with a high reliability.

It is thus possible to provide a highly reliable semiconductor memory device that can prevent short circuit between the control electrode 33 and the second charge accumulation layer 23 via the contact 71.

While certain embodiments have been described, these embodiments have been presented byway of example only and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device, comprising;
a first array of memory cells, each cell in the array positioned between a first semiconductor layer and an intermediate insulator;
a second array of memory cells, each cell in the array positioned between the intermediate insulator and a second semiconductor layer; and
a control electrode having a first electrode portion having a first width extending across a side surface of a first memory cell in the first array and a second memory cell in the second array and a second electrode portion having a second width located at a position peripheral to the memory cell array, the second width being larger than the first width.

2. The semiconductor memory device of claim 1, further comprising a contact extending from the second portion of the control electrode.

3. The semiconductor memory device of claim 2, wherein the first array includes a stacked unit having a charge accumulation layer, the stacked unit extending, adjacent to the control electrode, to a periphery of the memory cell array

4. The semiconductor memory device of claim 3, wherein the stacked unit includes a first portion extending in a first generally straight line path, and a second portion extending in a second generally straight line path different than the first generally straight line path.

5. The semiconductor memory device of claim 4, further including multiple first portions of the stacked unit extending in a first generally straight line path, and second portions of the stacked unit extending in a second generally straight line path different than the first generally straight line path, wherein the first portions are generally parallel to one another and separated by third electrode portions of the control electrode and the second portions are generally parallel to one another and separated by fourth electrode portions of the control electrode extending therebetween.

6. The semiconductor memory device of claim 5, wherein the third electrode portions are wider than the fourth electrode portions.

7. The semiconductor memory device of claim 5, wherein the control electrode overlie the side wall of the second portion; and
the contact extends into contact with the control electrode adjacent to, but spaced from, the portion of the control electrode extending along the sidewall of the second portion.

8. The semiconductor memory device of claim 5, wherein the control electrode overlies the side wall of the second portion of the charge accumulation layer; and
the contact extends into contact with the control electrode on the portion of the control electrode extending along the sidewall of the second portion of the charge accumulation layer.

9. The semiconductor memory device of claim 5, further including a plurality of second electrode portions arranged along an axis; and
a plurality of contacts, each contact contacting a different one of the plurality of the second electrode portions.

10. A semiconductor memory device comprising:
a first semiconductor layer that extends in the first direction,
a first gate-insulating film arranged on the first semiconductor layer,
first charge accumulation layers that are arranged on the first gate-insulating film and are separated from each other in the first direction and in the second direction crossing the first direction,
an insulating film arranged on each of the first charge accumulation layers,
second charge accumulation layers separated from each other in the first direction and in the second direction, each of the second charge accumulation layers being arranged on the insulating film
a second gate-insulating film arranged on the second charge accumulation layers,
a second semiconductor layer that is arranged on the second gate-insulating film and that extends in the first direction,
an intermediate insulating film arranged on the side surface of the first charge accumulation layers and the side surface of the second charge accumulation layers, and
a control electrode that is arranged on the side surface of the intermediate insulating film and extends in the second direction, the control electrode having a side-surface portion facing the side surfaces of the first charge accumulation layers and the side surfaces of the second charge accumulation layers via the intermediate insulating film and a pad portion arranged monolithically with the lower portion of the side-surface portion and has a width larger than the film thickness of the side-surface portion.

11. The semiconductor memory device according to claim 10, wherein the width of the pad portion of the control electrode is larger than the distance between the first charge accumulation layers adjacent to each other in the first direction and the distance between the second charge accumulation layers.

12. The semiconductor memory device according to claim 11, wherein the side-surface portion of the control electrode arranged between the first charge accumulation layers and between the second charge accumulation layers adjacent to each other in the first direction is branched into two portions in the second direction, and the branched side-surface portions are then merged at the pad portion.

13. The semiconductor memory device of claim 11, further including a contact extending from the pad portion of the control electrode.

14. The semiconductor memory device of claim 13, wherein the contact is isolated from a sidewall portion of the control electrode extending along the side wall of the charge accumulation layer.

15. The semiconductor memory device of claim 13, wherein the contact contacts a sidewall portion of the control electrode extending along the side wall of the charge accumulation layer.

16. A manufacturing method of a semiconductor memory device, comprising:
forming laminate portions on a foundation layer, each of the laminate portions including a first charge accumulation layer, an insulating layer disposed on the first charge accumulation layer and a second charge accumulation layer disposed on the insulating layer,
each of the laminate portions having line portions and a wide portion, the line portions separated from each other by a space in a first direction parallel to the foundation layer and extending in a second direction crossing the first direction, the wide portion connecting a pair of the line portions at an end-portion of the second direction and having a width larger than the width of each of the line portions;
forming a control electrode material film that buries the space and covers the foundation layer and the laminate portions;
forming a resist film on a region between the adjacent wide portions;
etching back the control electrode material film to remove the control electrode material film from a region having a larger width than the space and to left the control electrode material film disposed on the side surface of the line portion, on the side surface of the wide portion and below the resist film
removing a portion of the wide portion and a portion of the control electrode material film covered by the resist film to separate the pair of the line portions connected to each other via the wide portion;
forming a contact on the control electrode material film left in the region between the adjacent wide portions.

17. The manufacturing method of the semiconductor memory device according to claim 16, wherein the plural wide portions are formed side by side in the second direction.

18. The manufacturing method of claim 16, wherein the control electrode film extends over a side of the laminate and the contact is spaced therefrom.

19. The manufacturing method of claim 16, wherein the control electrode film extends over a side of the laminate and the contact is in contact therewith.
